(19) United States
(12) Patent Application Publication
(10) Pub. No.: US 2025/0140621 A1
(43) Pub. Date: May 1, 2025

(54) Stacked Power Converter Assembly

(71) Applicant: Lotus Microsystems APS, Hvidovre (DK)

(72) Inventors: Ahmed Morsi Ammar, Copenhagen (DK); Yasser A. Nour, Copenhagen (DK); HoàLê Thanh, Copenhagen (DK)

(21) Appl. No.: 18/836,074

(22) PCT Filed: Feb. 7, 2023
(86) PCT No.: PCT/EP2023/052977

§ 371 Date: Aug. 6, 2024

(30) Foreign Application Priority Data
Feb. 7, 2022 (EP) 22155495.9

(51) Int. Cl. H01L 23/31; H01L 23/00; H01L 23/498; H01L 23/66; H01L 25/16; H02M 3/00

(52) U.S. Cl. CPC H01L 23/3121; H01L 23/49838; H01L 23/66; H01L 24/16; H01L 25/16; H02M 3/003; H01L 2224/16227; H01L 2924/15321; H01L 2924/19041; H01L 2924/19042

(57) ABSTRACT

The present disclosure relates to a stacked power converter assembly comprising: an interposer. one or more integrated circuits, such as power management integrated circuits. arranged on top of the interposer: one or more passive electrical components stacked on top of the one or more integrated circuits and one or more current-carrying metal strips arranged and connected between the one or more passive electrical components and the interposer, wherein the one or more integrated circuits and the one or more passive electrical components are configured to perform a power conversion of an input voltage and/or current to an output voltage and/or current. It also discloses a method of assembling a stacked power converter comprising the steps of: providing an interposer: placing one or more integrated circuits on the interposer: placing one or more current-carrying metal strips on the interposer: and placing one or more passive electrical components on the current-carrying metal strips.

The present disclosure relates to a stacked power converter assembly, in particular to a high-power density DC-DC converter.

### BACKGROUND

In smart electronics systems, for example, internet of things (IoT) devices, light-emitting diode (LED) lightings, and other consumer electronic products, a general trend is that an increasing number of functions is packed into a limited space. These systems consequently require more compact and more efficient power converters, preferably also with lower manufacturing costs.

Miniaturized power converters play an important role in achieving the aforementioned goals and can be categorized into three categories. The first category is Power systems on chip (PwrSoC), in which all active and passive components are integrated on the same die. The second category is power system in package (PwrSiP) in which individual components of the converter are co-packaged together with a power management integrated circuits die. The third category is power modules in which pre-packaged discrete components are assembled on a printed circuit board.

One challenge with developing smaller power converters is miniaturization. The development towards smaller power converters typically implies smarter 3D layouts to fill as many features as possible on a given space. This implies manufacturing complexity and therefore high cost.

There is thus a need for a solution for stacked power converters with improved space layout, while keeping the manufacturing process simple and the associated cost low.

### SUMMARY

The present disclosure relates to a stacked power converter assembly for performing a power conversion of an input voltage and/or current to an output voltage and/or current. According to a first embodiment, the stacked power converter assembly comprises:
an interposer;
one or more integrated circuits, such as power management integrated circuits, arranged on top of the interposer;
one or more passive electrical components stacked on top of the one or more integrated circuits; and
one or more current-carrying metal strips arranged and connected between the one or more passive electrical components and the interposer;
   wherein the one or more integrated circuits and the one or more passive electrical components are configured to perform a power conversion of an input voltage and/or current to an output voltage and/or current.

On top of the interposer is arranged and connected one or more integrated circuits and one or more current-carrying metal strips. More specifically, the one or more integrated circuits may be a power management integrated circuit for a power converter, such as a buck converter. The one or more current-carrying metal strips may be zero-ohm surface-mount device resistors or metal jumpers. One advantage of having zero-ohm surface-mount device resistors or metal jumpers is that they can, at the same time, carry at least some of the weight of the one or more passive electrical components, which are stacked on top of the one or more integrated circuits and connected to the current-carrying metal strips, and carry a relatively high electrical current of the power converter. Alternatively, the one or more current-carrying metal strips can be capacitors. The one or more current-carrying metal strips are configured for carrying a relatively high electrical current of the stacked power converter assembly, which is further described below. The one or more passive electrical components can be an inductor, which is typically the largest passive electrical component in a power converter. By having the one or more passive electrical components stacked on top of the one or more integrated circuits, the stacked power converter surface area can be significantly reduced compared to the conventional side-by-side structure. Another advantage of having capacitors as the one or more current-carrying metal strips is that the capacitors can be directly connected with one terminal of the one or more passive electrical components, such as an inductor. In most of the power converter architectures, inductors may advantageously be connected to capacitors to conduct a filtering function. FIG. 1 presents an exemplary layout of the presently disclosed stacked power converter assembly.

According to one embodiment, one or more secondary passive electrical components, namely capacitors, may be arranged and connected on top of the interposer. More specifically, the one or more capacitors may be used to suppress switching noise generated by the power conversion. Alternatively, or additionally, secondary passive electrical components can be arranged on the interposer next to the one or more integrated circuits.

The stacked power converter may be encapsulated in a molding material, more specifically an epoxy molding compound. This can be achieved in multiple ways, with different epoxy molding compounds for the same stacked power converter assembly. Preferably, the one or more integrated circuits and the one or more current-carrying metal strips may be encapsulated in order to make the stacked power converter assembly more robust and resilient to mechanical stress.

The present disclosure further relates to a method of assembling a stacked power converter comprising the steps of:
providing an interposer;
placing and soldering one or more integrated circuits on the interposer;
placing and soldering one or more current-carrying metal strips on the interposer; and
placing and soldering one or more passive electrical components on the current-carrying metal strips.

This method provides the different steps of building a stacked power converter. A first assembly comprises the one or more integrated circuits and the one or more current-carrying metal strips, arranged and connected on top of the interposer. This first assembly may be encapsulated in a first molding material, more specifically an epoxy molding compound. After grinding the upper side of the first assembly until upper surfaces of the one or more current-carrying metal strips are exposed, a second assembly consists of the one or more passive electrical components, arranged and connected to the current-carrying metal strips upper surfaces. The second assembly can be encapsulated in a second molding material, more specifically an epoxy molding compound. FIG. 7A-D present the different encapsulation possibilities for the stacked power converter. Alternatively, the one or more integrated circuits, the one or more current-carrying metal strips and the one or more passive electrical components can be encapsulated in one molding process.

As a person skilled in the art would understand, the method described is applicable to any embodiment of the stacked power converter and vice versa.

### DESCRIPTION OF DRAWINGS

FIG. 1 shows a cross-section of an embodiment of the presently disclosed stacked power converter assembly.

FIG. 2 shows a cross-section of an embodiment of the presently disclosed stacked power converter assembly, having a secondary passive electrical component next to an integrated circuit.

FIG. 3A-H show cross-sections from a front view and a side view of embodiments of the presently disclosed stacked power converter assembly with different current-carrying metal strip structures.

FIG. 4 presents a perspective view of an embodiment of the presently disclosed stacked power converter assembly.

FIG. 5 presents a perspective view of an embodiment of the presently disclosed stacked power converter assembly with a transparent encapsulating material.

FIG. 6 presents an exploded view of an embodiment of the presently disclosed stacked power converter assembly.

FIG. 7A-D present flow-charts for embodiments of the presently disclosed method of assembling a stacked power converter.

### DETAILED DESCRIPTION

The present disclosure relates to a stacked electronic circuit assembly. According to a first embodiment, the stacked electronic circuit assembly comprises:
an interposer;
one or more integrated circuits, arranged on top of the interposer;
one or more passive electrical components stacked on top of the one or more integrated circuits; and
one or more metal strips arranged and connected between the one or more passive electrical components and the interposer.

Preferably, the stacked electronic circuit assembly is a stacked power converter assembly.

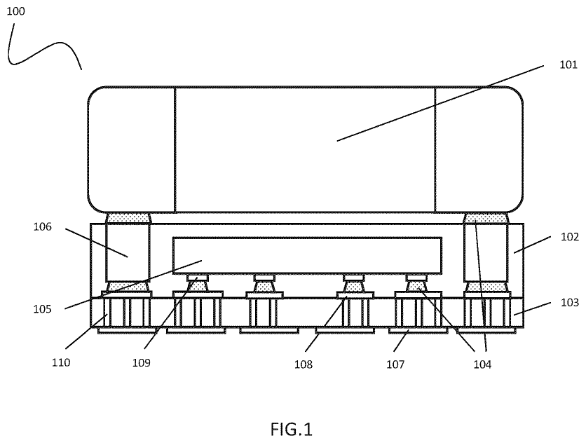

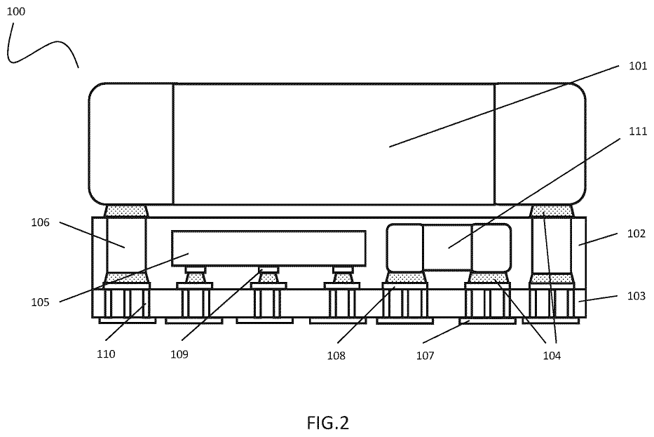

FIG. 1 shows a cross-section view of an example of an embodiment of a stacked power converter (100). On top of the interposer (103) is arranged an integrated circuit (105) and two current-carrying metal strips (106). Additionally, as presented in FIG. 2, a secondary passive electrical component (111) can be arranged on top of the interposer and next to the integrated circuit (105). A passive electrical component (101) is arranged on top of the current-carrying metal strips (106).

The stacked power converter (100) can be a DC-DC power converter assembly. Preferably, it has multiple input voltage levels and can deliver multiple output voltage levels. The one or more integrated circuits (105) may be configured to manage a number of power conversion rates between the input voltage levels and the output voltage levels. Practical power converters use switching techniques. Switched-mode DC-to-DC converters convert one DC voltage level to another, which may be higher or lower, by storing the input energy temporarily and then releasing that energy to the output at a different voltage.

The surface of the stacked power converter (100) can be relatively small in order to be integrated in embedded devices. In one embodiment, the surface is less than 20 mm² but preferably less than 10 mm², more preferably less than 6 mm², even more preferably less than 4 mm², most preferably less than 1 mm² to fit any application or device. In one embodiment, the stacked power converter (100) has a maximum height of 10 mm, preferably 6 mm, more preferably 4 mm, most preferably 2 mm. For wearable devices such as hearing aids or smart watches, small power converters allow an integration of more additional features for the same device size. This makes a device more technologically advanced while not modifying the package.

The interposer (103) is preferably a printed-circuit board (PCB) but can be a lead-frame substrate or a silicon substrate. The silicon substrate has the advantage of presenting a superior thermal performance compared to the two other options. The PCB may have at least two layers but can have further layers, such as three or four layers. The layers may be provided to match the bottom pads with the top pads of the PCB, while electrically connecting the different electrical elements of the stacked power converter, such as the integrated circuit (105) with the secondary passive electrical component (111). The intermediate layers of the PCB can be used to provide a heat dissipation and/or noise immunity by being designed as a ground plane. The connections between the different layers may be handled by means of vias (110). The top layer of the PCB (108) offers pads on which the one or more integrated circuits (105), the current-carrying metal strips (106) and the secondary passive components (111) can be mounted and soldered with solder balls (104). The bottom layer of the PCB (107) includes pads that match the required footprint of a package such as a Land-Grid Array (LGA), Quad Flat No-Lead (QFN) or Dual Flat No-Leads (DFN), on which the stacked power converter (100) can be arranged. While the LGA provides a type of surface-mount packaging for integrated circuits that is notable for having the pins on the socket, the QFN and DFN are flat no-leads package that physically and electrically connect integrated circuits to printed circuit boards. LGA is more particularly a packaging technology with a rectangular grid of contacts, on the underside of a package. Not all rows and columns of the grid need to be used. The contacts can either be made by using an LGA socket, or by using solder paste. The QFN and DFN present the advantage of offering a reduced inductance, a small sized “near chip scale” footprint, thin profile and low weight.

The one or more passive electrical components (101) arranged on top of the stacked power converter (100) can be a chip inductor, a chip capacitor or a ceramic capacitor. These passive electrical components may be Surface Mount-Device (SMD) components. In most of the power converter systems, the chip inductors tend to be the largest passive electrical components. Indeed, in magnetic DC-DC power converters, energy is periodically stored within and released from a magnetic field in an inductor, typically within a frequency range of 300 kHz to 10 MHz. By adjusting the duty cycle of the charging signal, the amount of power transferred to a load can be more easily controlled, though this control can also be applied to the input current, the output current or to maintain constant power. Power converters such as buck-boost, buck or boost are the heart of a switched-mode power supply. Chip inductors are the keys of this power conversion and, as previously mentioned, tend to be relatively large.

Therefore, it is an advantage to place the chip inductor on top of the stack in order to minimize the surface of the power converter.

The one or more secondary passive electrical components (111) are arranged next to the one or more integrated circuits (105) and on top of the interposer (103), as presented in FIG. 2. They can be electrically connected to the interposer through solder balls (104) on the interposer top layer (108). They can provide additional features to the stacked power converter (100). For instance, a small capacitor can suppress some of the switching noise caused by switching converters.

The current-carrying metal strips (106) may carry at least some of the weight of the one or more passive electrical components (101) and may carry the high electrical current flowing between the interposer (103) and the one or more passive electrical components (101). If the interposer (103) and/or the integrated circuit (105) and/or the current-carrying metal strips (106) are encapsulated in a molding material (102), the molding material may also assist in carrying at least some of the weight of the one or more passive electrical components (101) FIG. 1 and FIG. 2 present the placement of the current-carrying metal strips (106). In these figures, there are only two current-carrying metal strips because only one passive electrical component is arranged on top of the stack. Due to the potential electrical high current flowing between the interposer and the one or more passive electrical components, the current-carrying metal strips may be configured to carry a predefined minimum electrical current. In one embodiment, the high electrical current of the stacked power converter assembly is at least 10 mA, preferably at least 0.1 A, more preferably at least 1 A, even more preferably at least 50A, such as 100 A. Metal strips may be referred as being high-power resistors having a very low resistance values and outer terminations for soldering onto an interposer.

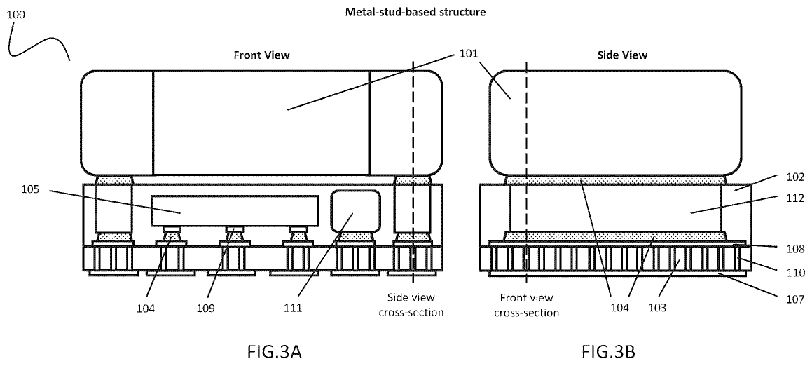

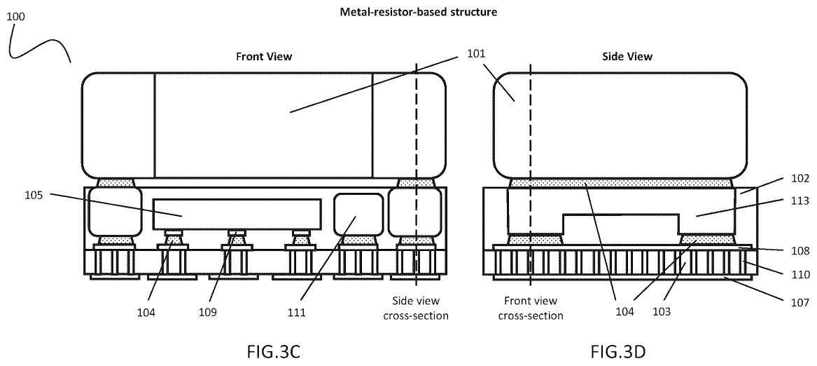

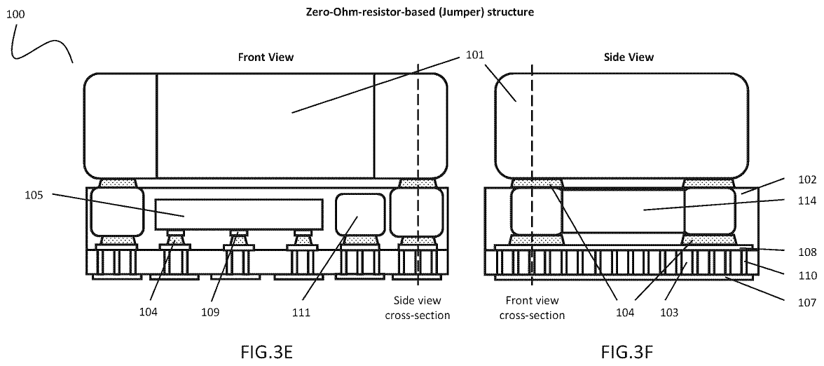

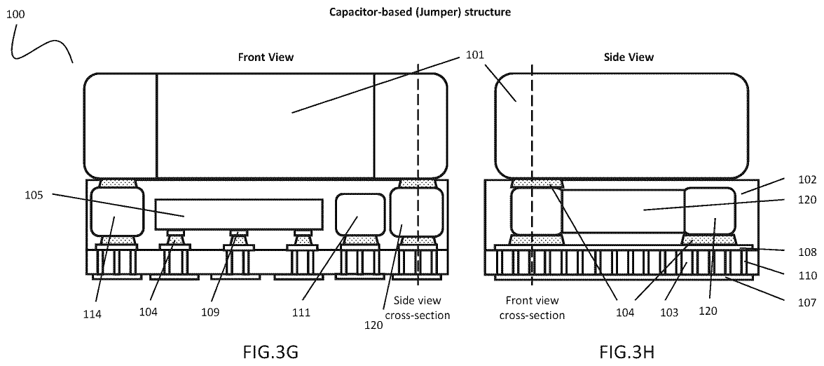

FIG. 3A-F present different types and structures of current-carrying metal strips that can be arranged on top of the interposer. FIG. 3A-B shows a cross-section of a front and a side view of an embodiment of the stacked power converter (100) where metal studs (112) are used as current-carrying metal strips. A metal stud is a metal strip that does not necessarily match the standard sizes of the surface-mount technology (SMT) component. Consequently, the metal stud can be custom designed. This allows any type of shape, where it can be a large copper sheet of a specified thickness, which is laser cut into small and thin metal sheets of a chosen dimension. The only requirement on the custom-designed metal stud dimension is that it needs to be compatible with standard pick-and-place assembly machines for automated assembly. This makes the metal stud option a very good solution for custom-based assembly, which allows different combinations of integrated circuits and secondary passive electrical component sizes to be arranged on top of the interposer. FIG. 3C-D shows a cross-section of a front and a side view of an embodiment of the stacked power converter (100) where metal resistors (113) are used as current-carrying metal strips. Metal resistors are based on standard SMT sizes such as 0201, 0402 or 0603. One possible variant of a metal resistor is a metal jumper. FIG. 3E-F shows a cross-section of a front and a side view of an embodiment of the stacked power converter (100) where zero-ohm resistors (114) are used as current-carrying metal strips. The zero-ohm resistors offer the benefit of being surface-mounted device (SMD) size based, and are available on the electronic market at a relatively cheap price. One difference between the metal resistor and the zero-ohm resistor based structure resides in the size of the upper surface of the component, therefore the available size of the contact for soldering the passive electrical component (101) contact. Zero-ohm resistors may have a substantially rigid body, which make them useful for carrying at least some of the weight of the passive electrical component(s). In one embodiment, the one or more current-carrying metal strips comprises at least one resistor, such as a zero-ohm resistor, at one end of the interposer, and at least one capacitor, such as an SMD capacitor, at an opposite end of the interposer FIG. 3G-H shows a cross-section of a front and a side view of an embodiment of the stacked power converter (100) where one capacitor (120) is used as a current-carrying metal strip, while the other current-carrying metal strip employs a zero-ohm resistor (114). Like resistors, capacitors offer a benefit of potentially being surface-mounted device (SMD) size based, and are available on the electronic market at a relatively cheap price. Capacitors may have a substantially rigid body, which make them useful for carrying at least some of the weight of the passive electrical component(s). In this specific configuration, the molding material (102) can also be used as an isolation between one of the capacitor terminal and the passive electrical component(s), as shown in FIG. 3H, where one capacitor terminal is not connected to the passive electrical component(s), i.e. one of the capacitor terminals is connected to the passive component(s). In the case where the passive electrical component(s) is one or more inductors, the molding material can be advantageously used to isolate one capacitor terminal with the one or more inductors, thereby making the stacked power converter structure useful for implementations such as buck, boost or buck-boost DC-to-DC converters. Nevertheless, having these four options of implementing the current-carrying metal strips gives flexibility on the cost and the shape of the assembly when designing and producing the stacked power converter.

The current-carrying metal strips can be capacitors, preferably SMD capacitors. Advantageously, in most of the power management systems, capacitors are directly connected to inductors. By having capacitors used as current-carrying metal strips, a direct connection can be made between capacitors and inductors. In power converter architectures such as buck, boost and buck-boost power converters, one terminal of the inductor may be connected to the one or more integrated circuits as described herein, such as power management integrated circuits, and the other terminal of the inductor may either be connected to capacitors or other connections such as ground. Specifically, in the case of a boost power converter, one of the inductor terminal may be connected to an input capacitor, in the case of a buck power converter, one of the inductor terminal may be connected to an output capacitor, and in the case of a buck-boost power converter, one of the inductor terminal may be connected to ground.

Buck, boost and buck-boost are different types of non-isolated switching DC-to-DC converter topologies. They convert one DC voltage level to another, which may be higher or lower, by storing the input energy temporarily and then releasing that energy to the output at a different voltage. The storage may be in either magnetic field storage components, such as inductors, or electric field storage components, such as capacitors. Switching conversion is often more power-efficient than linear voltage regulation, which dissipates considerable power loss as heat. Fast semiconductor device rise and fall times may be required to optimize the efficiency. However, these fast transitions combine with layout parasitic effects to make circuit design challenging. By implementing capacitors as current-carrying and, preferably, weight bearing, metal strips as disclosed herein, the connections between capacitors and inductors are either direct or extremely short, therefore minimizing the parasitic effects due to their physical implementation, therefore maximizing efficiency for a given design.

In such power converter topologies such as buck, boost or buck-boost, only one side of the capacitor may be connected to the inductor terminal through an opening in the molding material, while the other capacitor terminal is connected to ground and isolated from the inductor by the molding material. In case of a boost converter, the capacitor is the input capacitor, and the inductor is connected to the input voltage terminal of the capacitor, while the other capacitor terminal is connected to ground and isolated from the inductor. In case of a buck converter, the capacitor is the output capacitor, and the inductor is connected to the output voltage terminal of the capacitor, while the other capacitor terminal is connected to ground and isolated from the inductor. In case of a buck-boost converter, the capacitor is either the input or output capacitor, and the inductor is connected to the ground terminal of the capacitor, while the other capacitor terminal is isolated from the inductor. In all cases, the other inductor terminal is connected to the switching node of the chip through a current-carrying strip that is either a metal pillar, such as a metal strip, or a zero-ohm resistor, such as a zero-ohm SMD resistor. The switching node of the chip may be a node from the one or more integrated circuits or a node from the one or more passive electrical components as described in this application.

One advantage of such configuration, wherein the DC-to-DC converter uses the converter input or output capacitor as one of the current-carrying strip is the integration of that additional passive electrical component into the stacked structure, and the potential reduction of additional external electrical components that may need to be added on an associated application board. Application boards can be used in order to connect different systems in a controlled manner. By reducing the complexity of the application board associated to the system as disclosed herein, cost can be reduced, as well as the size of the application board.

Advantageously, SMD components, such as zero-ohm resistors or capacitors, or metal jumpers have flat surfaces. This may allow the current-carrying metal strips to be soldered on both sides, such as a top surface and a bottom surface, without forming recesses. By not having to form any recesses, the fabrication can be achieved according to SMD standards. The mounting and/or soldering of SMD components can be performed on flat surfaces, which can be processed by any systems configured for SMD standards. Accordingly, in one embodiment of the presently disclosed stacked power converter assembly, each of the one or more current-carrying metal strips have one or more substantially flat bottom surfaces.

The current-carrying metal strips may have an upper surface of at least 0.1 mm², preferably at least 0.2 mm², more preferably 0.4 mm² and even more preferably 0.5 mm². This makes them able to carry the weight of a large passive electrical component. This upper surface also gives a relatively solid platform to arrange the one or more passive electrical components on it. The one or more passive electrical components may have terminals that are arranged directly on upper surfaces of the one or more current-carrying metal strips.

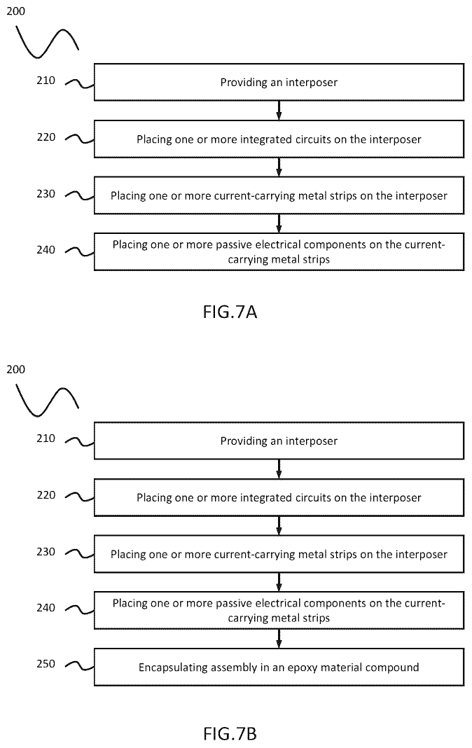

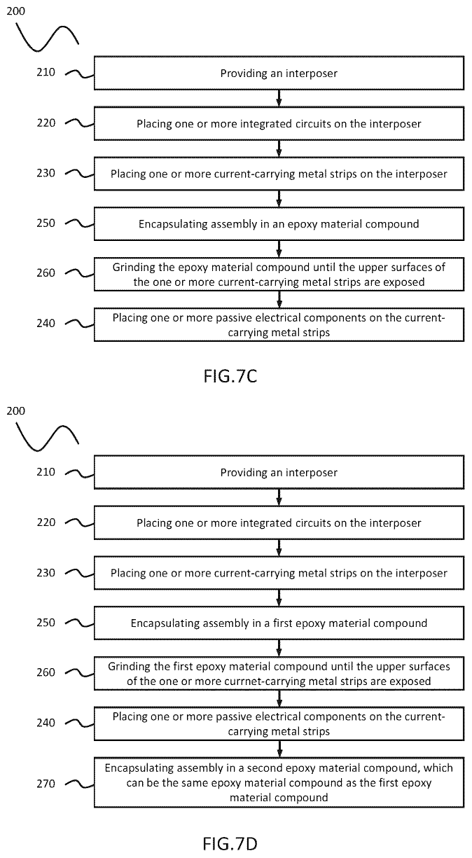

The stacked power converter assembly may follow a method of assembly which is described in FIG. 7A-D. FIG. 7A describes the method of assembling the presently disclosed stacked power converter without any encapsulation. This has the benefit of reducing the cost of the assembly, as well as the time it takes to make it. The stacked power converter assembly can be encapsulated in an epoxy molding material (102) according to a method described in FIG. 7B-D. The molding material is an epoxy molding compound, such as epoxy loaded with FusedSilica, CrystalineSilica or Alumina to enhance mechanical and/or electrical characteristics. Epoxy molding compounds are described as protection of semiconductor circuits from factors in the external environment such as moisture, heat, and shock. It can also be used to shield inductors in order to limit any radiations that can affect the surrounding circuits. Epoxy molding compound main ingredients are epoxy resin, hardener, silica, and other additives. Encapsulating the stacked power converter assembly in an epoxy molding compound can protect it against several aggressions from the outside environment, thus making it more reliable. Several options for molding are available for this stacked power converter assembly, which are described in more details in the next paragraphs.

FIG. 7B shows a first option of assembling a stacked power converter, where the stacked power converter assembly is encapsulated in one molding material. After providing an interposer, placing one or more integrated circuits, one or more current-carrying metal strips on top of the interposer and placing one or more passive electrical components on the current-carrying metal strips, an encapsulation can then be realized by using an epoxy material compound described in the previous paragraph. FIG. 7C shows a second option, where the stacked power converter assembly is partly encapsulated. After providing an interposer, placing one or more integrated circuits and one or more current-carrying metal strips on the interposer, an encapsulation can then be realized by using an epoxy material compound. A grinding process then needs to be performed to get an access to the upper surface of the one or more current-carrying metal strips. This can be done with two steps. The first step preferably comprises a lapping process, which thins down the molded epoxy molding compound down to the current-carrying metal strips upper surface. Then an optional second step is a polishing process, which polishes the current-carrying metal strips upper surface to a desired roughness, thus increasing the adhesion of the solder. The one or more passive electrical components can be arranged on top of the current-carrying metal strips. FIG. 7D shows a third option which comprises the same steps as the second option previously described, but where the one or more passive electrical components, after being arranged on top of the encapsulated one or more current-carrying metal strips, interposer and the one or more integrated circuits, is encapsulated in the same or a different epoxy material compound.

The encapsulation in an epoxy material compound may be not necessary, and the stacked power converter can be built without any encapsulation.

### DETAILED DESCRIPTION OF DRAWINGS

The invention will in the following be described in greater detail with reference to the accompanying drawings. The drawings are exemplary and are intended to illustrate some of the features of the presently disclosed stacked power converter assembly, and are not to be construed as limiting to the presently disclosed invention.

FIG. 1 shows a cross-section view of the presently disclosed stacked power converter (100) assembly, having an interposer (103), on which an integrated circuit (105) and two current-carrying metal strips (106) are arranged on solder balls (104), connected to the interposer top layer (108). Some through-interposer-vias (110) are connecting the top layer (108) to the bottom layer (107) of the interposer (103). A passive electrical component (101) is arranged on top of the current-carrying metal strips (106). The interposer (103), the integrated circuit (105) and the current-carrying metal strips (106) are encapsulated in a molding material, more specifically an epoxy molding compound (102).

FIG. 2 shows a cross-section view of the presently disclosed stacked power converter (100) assembly, having an interposer (103), on which an integrated circuit (105), a secondary passive electrical component (111) and two current-carrying metal strips (106) are arranged on solder balls (104), connected to the interposer top layer (108). Some through-interposer-vias (110) are connecting the top layer (108) to the bottom layer (107) of the interposer. A passive electrical component (101) is arranged on top of the current-carrying metal strips (106). The interposer (103), the integrated circuit (105), the secondary passive electronic component (111) and the current-carrying metal strips (106) are encapsulated in a molding material, more specifically an epoxy molding compound (102).

FIG. 3A-H show cross-sections of the front view and side view of an embodiment of the presently disclosed stacked power converter (100) assembly with different current-carrying metal strips (106) structures. FIG. 3A-B present a cross-section of the front and side view of an embodiment of the presently disclosed stacked power converter (100) assembly having metal-studs (112) current-carrying metal strips. FIG. 3C-D present a cross-section of the front and side view of an embodiment of the presently disclosed stacked power converter assembly having metal-resistor (113) current-carrying metal strips. FIG. 3E-F present a cross-section of the front and side view of an embodiment of the presently disclosed stacked power converter assembly having zero-ohm-resistor (114) current-carrying metal strips. FIG. 3G-H present a cross-section of the front and side view of an embodiment of the presently disclosed stacked power converter (100) assembly having capacitors (120) as current-carrying metal strips.

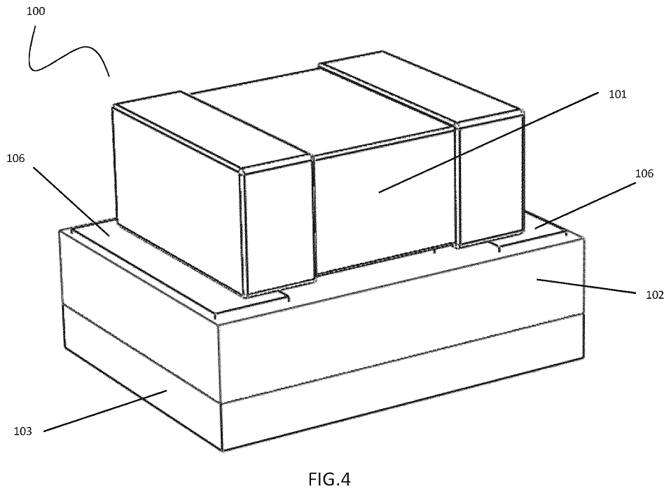

FIG. 4 shows a perspective view of an embodiment of the presently disclosed stacked power converter (100) assembly. The upper surface of two current-carrying metal strips (106) is presented, on which a passive electrical component is arranged (101).

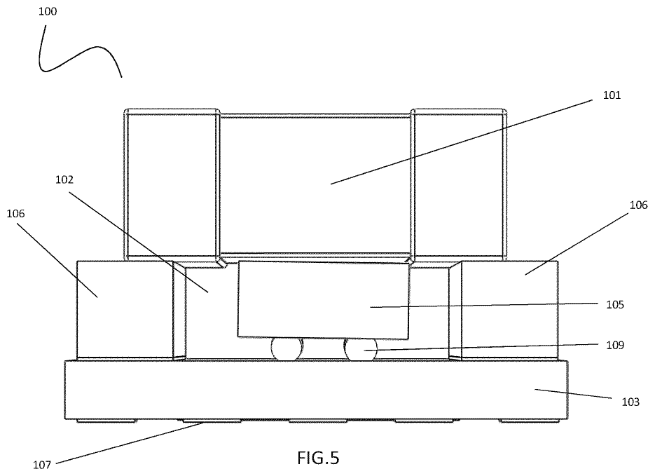

FIG. 5 shows a perspective view of an embodiment of the presently disclosed stacked power converter (100) assembly with a transparent encapsulating material (102) in order to see the encapsulated elements. An integrated circuit (105) is arranged on the interposer (103), while being connected to the interposer top layer through solder balls (104). Two current-carrying metal strips (106) are arranged on top of the interposer (103), on which is arranged a passive electrical component (101). The bottom layer of the interposer (107) is also presented.

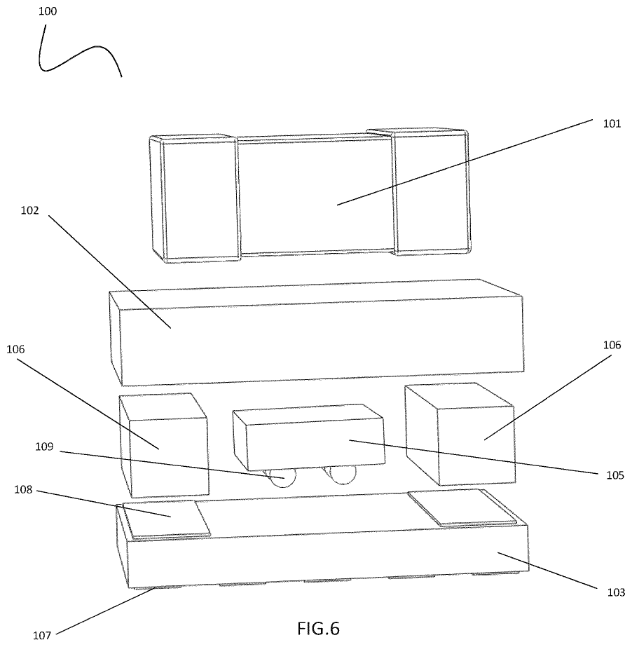

FIG. 6 shows an exploded view of an embodiment of the presently disclosed stacked power converter (100) assembly in order to see the different elements being arranged in the stack. An integrated circuit (105) is arranged on top of the interposer (103) on which it is soldered thanks to its integrated circuit pins (109). The interposer (103) has bottom (107) and top layers (108). Two current-carrying metal strips (106) are arranged on the top layer (108) of the interposer (103), on which is arranged a passive electrical component (101). The integrated circuit (105) and the current-carrying metal strips (106) are encapsulated in an epoxy molding compound (102) block.

FIG. 7A-D show flow-charts for embodiments of the presently disclosed method of assembling a stacked power converter (100). FIG. 7A presents the method (200) of assembling a stacked power converter, which consists of the steps of providing an interposer (210), placing one or more integrated circuits on the interposer (220), placing one or more current-carrying metal strips on the interposer (230) and placing one or more passive electrical components on the current-carrying metal strips (240). FIG. 7B presents the method (200) of assembling a stacked power converter, which consists of the steps of providing an interposer (210), placing one or more integrated circuits on the interposer (220), placing one or more current-carrying metal strips on the interposer (230), placing one or more passive electrical components on the current-carrying metal strips (240) and encapsulating the assembly in an epoxy material compound (250). FIG. 7C presents the method (200) of assembling a stacked power converter, which consists of the steps of providing an interposer (210), placing one or more integrated circuits on the interposer (220), placing one or more current-carrying metal strips on the interposer (230), encapsulating the assembly constituted by the previous steps in an epoxy material compound (250), grinding the epoxy material compound until the upper surfaces of the one or more current-carrying metal strips are exposed (260) and placing one or more passive electrical components on the current-carrying metal strips (240). FIG. 7D presents the method (200) of assembling a stacked power converter, which consists of the steps of providing an interposer (210), placing one or more integrated circuits on the interposer (220), placing one or more current-carrying metal strips on the interposer (230), encapsulating the assembly constituted by the previous steps in an epoxy material compound (250), grinding the epoxy material compound until the upper surfaces of the one or more current-carrying metal strips are exposed (260), placing one or more passive electrical components on the current-carrying metal strips (240) and encapsulating the assembly in a second epoxy material compound, which can be the same epoxy material compound as the first epoxy material compound (270).

### List of Elements in Figures

100—power converter assembly
101—passive electrical component
102—epoxy molding compound
103—interposer
104—solder ball
105—integrated circuit
106—current-carrying metal strips
107—interposer bottom layer
108—interposer top layer
109—integrated circuit pins
110—through-interposer-vias
111—secondary passive electrical component
112—metal stud
113—metal resistor
114—zero-ohm resistor
120—capacitor

### Further Details of the Invention

1. A stacked power converter assembly comprising:
   an interposer;
   one or more integrated circuits, such as power management integrated circuits, arranged on top of the interposer;
   one or more passive electrical components stacked on top of the one or more integrated circuits; and
   one or more current-carrying metal strips arranged and connected between the one or more passive electrical components and the interposer;
   wherein the one or more integrated circuits and the one or more passive electrical components are configured to perform a power conversion of an input voltage and/or current to an output voltage and/or current.
2. The stacked power converter assembly according to item 1, wherein the one or more passive electrical components are surface-mount device (SMD) components.
3. The stacked power converter assembly according to any one of the preceding items, wherein the one or more passive electrical components comprise a chip inductor and/or a chip capacitor and/or a ceramic capacitor.
4. The stacked power converter assembly according to any one of the preceding items, wherein the interposer is a printed circuit board, a lead-frame substrate or a silicon substrate.
5. The stacked power converter assembly according to item 4, wherein the interposer has two or more metal layers.
6. The stacked power converter assembly according to any one of the preceding items, wherein the one or more current-carrying metal strips carry the one or more passive electrical components.
7. The stacked power converter assembly according to item 6, wherein the one or more current-carrying metal strips are configured for carrying high electrical current of the stacked power converter assembly.
8. The stacked power converter assembly according to item 7, wherein the high electrical current of the stacked power converter assembly is at least 10 mA, preferably at least 0.1 A, more preferably at least 1 A, even more preferably at least 50 A, such as 100 A.
9. The stacked power converter assembly according to items 6-8, wherein each of the one or more current-carrying metal strips has an upper surface of at least 0.1 mm², preferably at least 0.2 mm², more preferably 0.4 mm² and even more preferably 0.5 mm².
10. The stacked power converter assembly according to any one of the preceding items, wherein the one or more current-carrying metal strips are zero-ohm SMD resistors.
11. The stacked power converter assembly according to any one of the preceding items, wherein the one or more current-carrying metal strips are metal jumpers and/or wherein the one or more current-carrying metal strips are metal clips, such as copper clips.
12. The stacked power converter assembly according to any one of the preceding items, further comprising a molding material encapsulating the one or more integrated circuits and/or the one or more current-carrying metal strips.
13. The stacked power converter assembly according to item 12, wherein the molding material is an epoxy molding compound.
14. The stacked power converter assembly according to items 12-13, wherein the molding material further encapsulates the one or more electrical passive components.
15. The stacked power converter assembly according to any one of the preceding items, wherein the stacked power converter assembly has a maximum surface of 20 mm², preferably a maximum surface of 10 mm², more preferably a maximum surface of 6 mm², even more preferably a maximum surface of 4 mm², most preferably a maximum surface of 1 mm².
16. The stacked power converter assembly according to any one of the preceding items, wherein the stacked power converter assembly has a maximum height of 10 mm, preferably 6 mm, more preferably 4 mm, most preferably 2 mm.
17. The stacked power converter assembly according to any one of the preceding items, wherein the stacked power converter assembly is a DC-DC power converter assembly.
18. The stacked power converter assembly according to item 17, wherein the DC-DC power converter has multiple input voltage levels and multiple output voltage levels and wherein the one or more integrated circuits is configured to manage a number of power conversion rates between the input voltage levels and output voltage levels.
19. The stacked power converter assembly according to any one of the preceding items, further comprising one or more secondary passive electrical components arranged on and connected to the interposer.
20. The stacked power converter assembly according to item 19, wherein the one or more secondary passive electrical components are capacitors.
21. A method of assembling a stacked power converter comprising the steps of:
   providing an interposer;
   placing and soldering one or more integrated circuits on the interposer;
   placing and soldering one or more current-carrying metal strips on the interposer; and
   placing and soldering one or more passive electrical components on the current-carrying metal strips.
22. The method of assembling a stacked power converter according to item 21, further comprising the step of encapsulating the one or more integrated circuits and the one or more current-carrying metal strips on the interposer in a first molding material by a first molding process before placing the one or more passive electrical components on the current-carrying metal strips.
23. The method of assembling a stacked power converter according to any one of items 21-22, further comprising the step of grinding the first molding material from an upper side until upper surfaces of the one or more current-carrying metal strips are exposed.
24. The method of assembling a stacked power converter according to any one of items 21-23, further comprising the step of encapsulating the one or more passive electrical components in a second molding material by a second molding process after placing the one or more passive electrical components on the current-carrying metal strips.
25. The method of assembling a stacked power converter according to item 21, further comprising the step of encapsulating the one or more integrated circuits, the one or more current-carrying metal strips and the one or more passive electrical components in one molding process.
26. The method of assembling a stacked power converter according to any one of items 21-25, wherein the stacked power converter is the stacked power converter according to any one of items 1-20.

1-20. (canceled)

21. A stacked power converter assembly comprising:
an interposer;
one or more integrated circuits arranged on top of the interposer;
one or more passive electrical components stacked on top of the one or more integrated circuits;
one or more current-carrying metal strips arranged and connected between the one or more passive electrical components and the interposer; and
wherein the one or more integrated circuits and the one or more passive electrical components are configured to perform a power conversion of an input voltage and/or current to an output voltage and/or current.

22. The stacked power converter assembly according to claim 21, wherein the one or more passive electrical components are surface-mount device (SMD) components.

23. The stacked power converter assembly according to claim 21, wherein the one or more passive electrical components comprise a chip inductor and/or a chip capacitor and/or a ceramic capacitor.

24. The stacked power converter assembly according to claim 21, wherein the interposer is a printed circuit board, a lead-frame substrate, or a silicon substrate.

25. The stacked power converter assembly according to claim 21, wherein the one or more current-carrying metal strips have one or more substantially flat bottom surfaces.

26. The stacked power converter assembly according to claim 21, wherein the one or more current-carrying metal strips carry the one or more passive electrical components.

27. The stacked power converter assembly according to claim 26, wherein the one or more current-carrying metal strips are configured to carry high electrical current of the stacked power converter assembly.

28. The stacked power converter assembly according to claim 27, wherein the high electrical current of the stacked power converter assembly is at least 10 mA.

29. The stacked power converter assembly according to claim 26, wherein each of the one or more current-carrying metal strips has an upper surface of at least 0.1 mm².

30. The stacked power converter assembly according to claim 21, wherein the one or more current-carrying metal strips are zero-ohm SMD resistors and/or SMD capacitors.

31. The stacked power converter assembly according to claim 21, wherein the one or more current-carrying metal strips comprises at least one resistor at one end of the interposer, and at least one capacitor at an opposite end of the interposer.

32. The stacked power converter assembly according to claim 31, wherein the at least one resistor is a zero ohm resistor, and wherein the at least one capacitor is an SMD capacitor.

33. The stacked power converter assembly according to claim 21, wherein the one or more current-carrying metal strips are metal jumpers and/or wherein the one or more current-carrying metal strips are metal clips.

34. The stacked power converter assembly according to claim 21, further comprising a molding material encapsulating the one or more integrated circuits and/or the one or more current-carrying metal strips.

35. The stacked power converter assembly according to claim 34, wherein the molding material further encapsulates the one or more electrical passive components.

36. The stacked power converter assembly according to claim 21, wherein the stacked power converter assembly has a maximum surface of 20 mm².

37. The stacked power converter assembly according to claim 21, wherein the stacked power converter assembly is a DC-DC power converter assembly, wherein the DC-DC power converter has multiple input voltage levels and multiple output voltage levels, and wherein the one or more integrated circuits is configured to manage a number of power conversion rates between the input voltage levels and output voltage levels.

38. The stacked power converter assembly according to claim 21, further comprising one or more secondary passive electrical components arranged on and connected to the interposer.

39. A method of assembling a stacked power converter, the method comprising:
providing an interposer;
placing and soldering one or more integrated circuits on the interposer;
placing and soldering one or more current-carrying metal strips on the interposer; and
placing and soldering one or more passive electrical components on the current-carrying metal strips.

40. The method of assembling a stacked power converter according to claim 39, further comprising:
encapsulating the one or more integrated circuits and the one or more current-carrying metal strips on the interposer in a first molding material by a first molding process before placing the one or more passive electrical components on the current-carrying metal strips;
grinding the first molding material from an upper side until upper surfaces of the one or more current-carrying metal strips are exposed; and
encapsulating the one or more passive electrical components in a second molding material by a second molding process after placing the one or more passive electrical components on the current-carrying metal strips.
